(19) United States
(12) Patent Application Publication
(10) Pub. No.: US 2012/0044647 A1
(43) Pub. Date: Feb. 23, 2012

(54) STRUCTURE FOR COOLING PARTS OF HEV

(75) Inventors: Jeong Yun Lee, Hwaseong (KR); Dongmin Shin, Hwaseong (KR); Wooyong Jeon, Seoul (KR); In Pil Yoo, Seoul (KR); Joon Hwan Kim, Seoul (KR); Jin Hwan Jung, Suwon (KR); Jung Hong Joo, Hwaseong (KR)

(73) Assignee: Hyundai Motor Company, Seoul (KR)

(21) Appl. No.: 12/954,005

(22) Filed: Nov. 24, 2010

(30) Foreign Application Priority Data
Aug. 20, 2010 (KR) 10-2010-0080990

(51) Int. Cl. H05K 7/20

(52) U.S. Cl. 361/702

(57) ABSTRACT

The present invention provides an apparatus for cooling parts of a hybrid electric vehicle. The apparatus cools the main heating parts of a motor driving system, including an inverter, in the HEV. A heat dissipater may also be provided and equipped with different heating parts, such that the heating parts share the heat dissipater. A channel for a coolant to flow is formed in the heat dissipater, and the heat dissipater defines heat transfer paths for transferring heat generated from the heating parts to the coolant. The heating parts include a power module, an inductor, and a film capacitor.

### CROSS-REFERENCE TO RELATED APPLICATION

This application claims priority to and the benefit of Korean Patent Application No. 10-2010-0080990 filed in the Korean Intellectual Property Office on Aug. 20, 2010, the entire contents of which are incorporated herein by reference.

### BACKGROUND OF THE INVENTION

(a) Field of the Invention

The present invention relates to cooling systems within hybrid vehicle or an electric/fuel battery vehicle. More particularly, the present invention relates to a cooling apparatus for cooling main heating parts of a motor driving system, such as an inverter.

(b) Description of the Related Art

Recently, research into electric/fuel battery vehicles also known as hybrid vehicles has increased because of growing demands for enhancement of fuel efficiency and reinforcement of exhaust gas regulations in consideration of green energy.

Hybrid vehicles use an engine and high power motors as power sources and are equipped with a motor driving system as an inverter that converts high-voltage DC power generated from a battery or a cell into 3-phase AC power of U, V, and W in order to charge and discharge electric energy produced therein.

The motor driving system is equipped with a power module, an inductor, and a film capacitor, as main heating parts, which generate heat in operation.

The power module and the inductor generate the largest amount of heat and further generate heat when the output of the motor increases to improve the output and fuel efficiency of the vehicles. Further, the film capacitor has a defect that the internal film cells are vulnerable to temperature, even though it has high voltage-resistance and durability.

In the related art, the motor driving system described above provides the power module, inductor and film capacitor in a housing.

In the motor driving system, the power module and the inductor are mounted to a water-cooling heat dissipater where cooling water flows. The film capacitor is mounted on the inner wall of the housing, separate from the heat dissipater, in order to cool the power module, inductor and film capacitor, which are the main heating parts.

Therefore, most of the heat from the power module and the inductor can be transferred to the cooling water through the heat dissipater and the heat from the film capacitor can be transferred to the engine room through the housing.

However, since the power module and the inductor are mounted to the heat dissipater in the related art, although it was possible to protect them against heat and increase durability, it was impossible to maximize the effect of cooling the film capacitor even if the heat from the film capacitor is transferred to the engine room through the housing, because the cooling water in the heat dissipater is lower in temperature than the engine room.

That is, only the power module and the inductor are cooled by cooling water without using a specific heat-dissipating apparatus, even though heat is further generated when the film capacitor is heated by ripple current and current increases.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention provides an apparatus or structure for cooling parts of a hybrid electric vehicle (HEV) having advantages that include increasing cooling efficiency of film capacitors within a motor driving system.

An exemplary embodiment of the present invention provides an apparatus for cooling parts of an HEV which cools the main heating parts of a motor driving system. The present invention including an inverter, in the HEV, in which a heat dissipater equipped with different heating parts is included. The heating parts may be configured to share the heat dissipater. Further, a channel for a coolant to flow is formed in the heat dissipater, and the heat dissipater defines heat transfer paths for transferring heat generated from the heating parts, including a power module, an inductor, and a film capacitor, to the coolant.

Further, in one embodiment of the apparatus for cooling parts of an HEV, the heat transfer path for the power module and the inductor and the heat transfer path for the film capacitor may be formed in the opposite directions, within the heat dissipater.

In a further embodiment, the heat dissipater may be equipped with the power module and the inductor on one side and the film capacitor on the other side.

In another embodiment, the heat dissipater may include a heat-dissipating plate forming the channel and a cover combined with the heat-dissipating plate and covering the channel.

In yet another embodiment, the power module and the inductor are disposed on a flat surface of the heat-dissipating plate and the film capacitor is disposed on a flat surface of the cover, in the heat dissipater.

In a further embodiment, the channel of the heat-dissipating plate may be formed in a zigzag shape and positioned between a plurality of ribs.

In another embodiment, the heat dissipater may be connected with an inverter housing covering the power module and the inductor.

In yet another embodiment, the apparatus for cooling parts of an HEV, the cover may function as a case for the film capacitor.

The present invention provides a number of benefits and advantages. The subject invention makes it possible to remove the heat from the power module, inductor, and film capacitor, which are heating parts, by using a coolant, such as water, in the water-cooling type, when the motor driving system operates.

Thus, in contrast to the related art, the temperature around where the film capacitor operates in the present invention is not the temperature of the engine room, but the temperature of the coolant that is relatively low, such that it is possible to additionally ensure tolerance in temperature to the limit temperature for the film capacitor.

Further, the present invention enables improved cooling efficiency for the entire motor driving system, because the film capacitor is mounted on the heat dissipater. In addition, the subject invention enables cooling of the power module and the inductor by using the heat dissipater.

In addition, the present invention maximizes the effect of cooling the entire motor driving system by making the temperature of the surrounding of the film capacitor at the level of the temperature of the coolant, rather than the temperature of the engine room. The present invention also provides improved commercial value and performance of a vehicle by increasing the capacity of the inverter, including the film capacitor.

Further, the present invention also reduces the entire size and weight of the motor driving system without using a specific heat-dissipating apparatus for cooling the film capacitor, because the power module and the inductor are mounted on one side of the heat dissipater and the film capacitor is mounted on the other side. As a result, the reduction of weight of the parts provides improved fuel efficiency of a vehicle and reduced manufacturing costs.

### BRIEF DESCRIPTION OF THE DRAWINGS

The drawings are provided to be referred in explaining exemplary embodiments of the present invention and the spirit of the present invention should not be construed as being limited be the accompanying figures.

FIG. 1 is a view schematically showing an apparatus for cooling parts of an HEV according to an exemplary embodiment of the present invention;

FIG. 2 is an exploded perspective view showing a heat dissipater used in the apparatus of FIG. 1; and

FIG. 3 is a view schematically showing another embodiment of an apparatus for cooling parts of an HEV according to the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification.

Further, In addition, the dimensions of each component shown in the drawings are not drawn to zie but are only forfor understanding and ease of description. The present invention is not limited to the dimensions illustrated, rather the thickness of parts, regions, etc., are exaggerated for clarity.

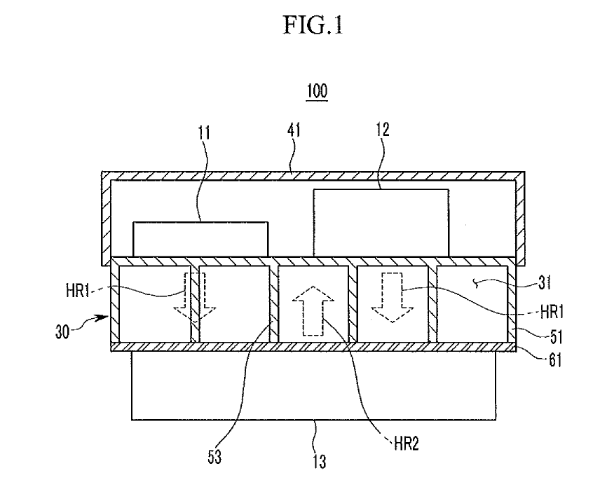

Turning to FIG. 1, a schematic view of an apparatus for cooling parts of an HEV according to an exemplary embodiment of the present invention is shown.

Referring to the FIG. 1, an apparatus 100 for cooling heating parts according to the exemplary embodiment of the present invention can be used for hybrid vehicles or electric/fuel battery vehicles equipped with an engine and high power motors as power sources.

In this embodiment, the apparatus 100 for cooling heating parts is used in a known hybrid electric vehicle.

The hybrid electric vehicle is equipped with a motor driving system for controlling a high power motor and the motor driving system may be an inverter that converts high-voltage DC power generated from a battery or a cell into high-voltage 3-phase AC power of U, V, and W.

The inverter may be composed of a power module 11. The power module 11 is a switching element for power conversion, such as a transformer. An inductor 12 that makes a motor operate as a driving power source or filters output voltage of the inverter is also shown along with a film capacitor 13 for absorbing ripple current from the power module 11.

In this configuration, the film capacitor 13 performs planarizing that suppresses sudden changes in DC input voltage of the inverter by absorbing the ripple current generated in inverter switching. This allows the inverter to is normally operate and increase durability of a high-voltage battery or a cell.

The apparatus 100 described above is adapted and configured to remove heat from the heating parts of the inverter. Heating parts include the power module 11, the inductor 12, and the film capacitor 13, which are described above.

The apparatus 100 according to the exemplary embodiment of the present invention has a structure that effectively cools the film capacitor 13 having high voltage-resistance and durability but including internal film cells, which are vulnerable to temperature, in addition to cooling the power module 11 and the inductor 12.

For this purpose, the apparatus 100 for cooling heating parts of hybrid electric vehicles according to the exemplary embodiment of the present invention includes a water-cooling heat dissipater 30 that can cool all the different heating parts 11, 12, and 13 with a coolant, such as cooling water.

In the exemplary embodiment, the heat dissipater 30 is equipped with the different heating parts 11, 12, and 13 such that the heating parts 11, 12, and 13 can share the coolant.

The heat dissipater 30 is a cooling plate having a channel 31 therein for the coolant to flow and may have heat transfer paths HR1 and HR2 for transferring heat from the power module 11, inductor 12, and film capacitor 13, to the coolant.

The heat dissipater 30 is made of a material having high thermal conductivity and heat dissipation performance, such as an aluminum alloy. The heat dissipater 30 may be fixed to the open end of an inverter housing 41 after being separately manufactured, as shown in the figures. Alternatively, the heat dissipater 30 may be integrally formed with the inverter housing 41, which is not shown in the figures.

In this embodiment, the heat dissipater 30 can cool the heating parts 11, 12, and 13 with the coolant flowing therein, by attaching the power module 11 and the inductor 12 to one side and the film capacitor 13 on the other side.

The coolant is typically cooling water, but may also be other known suitable coolants. Hereafter, the present invention will be described for illustrative purposes an apparatus using cooling water as a coolant. The cooling water can be supplied from the cooling system of a vehicle.

The heat dissipater 30 may include a heat-dissipating plate 51 having the channel 31 described above and a cover 61 combined with the heat-dissipating plate 51, covering the channel 31.

The heat-dissipating plate 51 is typically made of metal, such as an aluminum alloy, in a plate shape having a predetermined width, with the channel 31, which allows the coolant to flow, on the top.

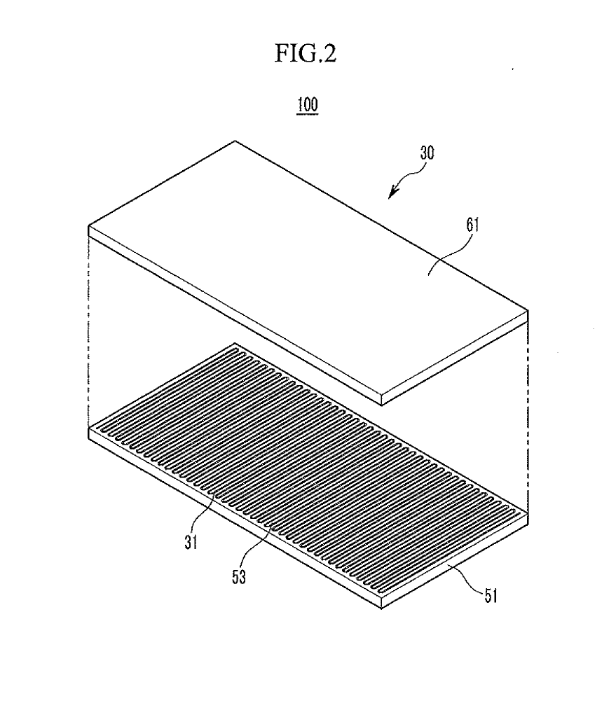

In this embodiment, the channel 31 may be formed in a zigzag shape on the heat-dissipating plate 51, as shown in FIG. 2, and the channel 31 may be positioned between a plurality of ribs (commonly called “fins” in this field).

In a further embodiment, the cover 61 is made of the same material as the heat-dissipating plate 51 and disposed on the heat-dissipating plate 51 such that the channel 31 is formed by the ribs 53.

A sealing pad (not shown), or gasket, may be disposed between the heat-dissipating plate 51 and the cover 61 to keep airtightness. In addition, the heat-dissipating plate 51 and the cover 61 may be combined by fasteners, such as bolts.

The heat dissipater 30 may be composed of the heat-dissipating plate 51 and the cover 61 having an inlet (not shown), for the coolant to flow into the channel 31, and an outlet (not shown), for discharging the coolant passing through the channel 31.

The power module 11 and the inductor 12, which are heating parts, may be disposed on the flat surface (the top in the figure) of the heat-dissipating plate 51 and the film capacitor 13 may be disposed on the flat surface (the bottom in the figure) of the cover 61, in the heat dissipater 30.

In this embodiment, because the power module 11 and the inverter 12 are fixed to the open end of the inverter housing 41, they can be covered by the inverter housing 41.

In this case, the power module 11 and the inductor 12 may be fastened to the flat surface of the heat-dissipating plate 51 by bolts and the film capacitor 13 may be fastened to the flat surface of the cover body 61 by bolts.

Therefore, the heat dissipater 30 according to the exemplary embodiment, as described above, defines the heat transfer paths HR1 and HR2 for transferring the heat from the power module 11, inductor 12, and film capacitor 13 to the coolant, where the heat transfer path HR1 for the power module 11 and the inductor 12 and the heat transfer path HR2 for the film capacitor 13 may be formed in the opposite directions.

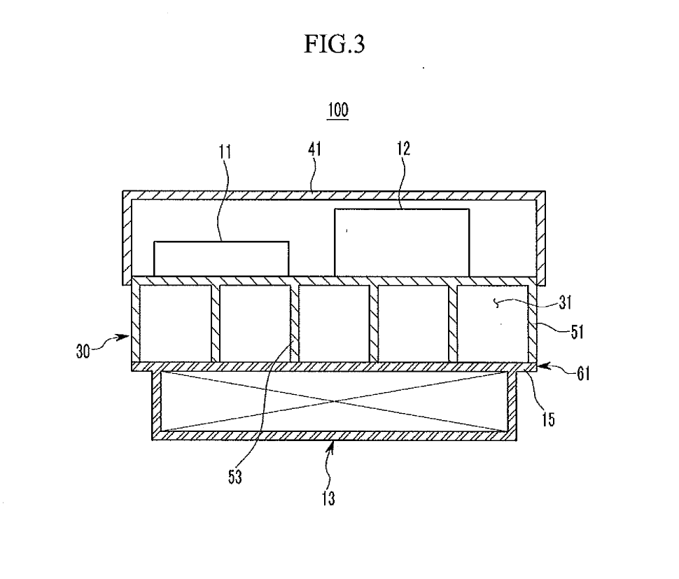

In a further embodiment, the cover 61 of the heat dissipater 30, as shown in FIG. 3, may be a case 15 for the film capacitor 13.

That is, the case 15 for the film capacitor 13 has spaces for accommodating the unit cells and the cover that covers the spaces may be the cover 61 of the heat dissipater 30.

The operation of the apparatus 100 for cooling heating parts of hybrid electric vehicles according to the exemplary embodiment of the present invention is described in detail with reference to the accompanying drawings.

In one exemplary embodiment, the power module 11 and the inductor 12 are mounted on the flat surface of the heat-dissipating plate 51, which is one side of the heat dissipater 30, and the film capacitor 13 is mounted on the flat surface of the cover 61, which is the other side of the heat dissipater 30.

Further, the power module 11 and the inductor 12 may be covered by the inverter housing 41, and the power module 11, inductor 12, and film capacitor 13, which are heating parts, and generate heat in the operation of the motor driving system.

In this state, as the coolant is supplied through the inlet (not shown) of the heat dissipater 30, the coolant flows through the channel 31 of the heat-dissipating plate 51 and is discharged from the outlet (not shown), such that it continuously circulates therein.

In this process, since the coolant circulates through the channel 31 in the heat dissipater 30, the heat from the power module 11 and the inductor 12 is transferred to the coolant circulating through the channel 31, so that it is removed.

In other words, most of the heat from the power module 11 and the inductor 12 can be transferred to the coolant, through the heat transfer path HR1 formed from the heat-dissipating plate 51 to the cover 61.

Simultaneously, the heat from the film capacitor 13 is transferred to the coolant circulating through the channel 31 and removed. In other words, most of the heat can be transferred to the coolant, through the heat transfer path HR2 formed from the cover 61 to the heat-dissipating plate 51.

Therefore, in this exemplary embodiment, it is possible to remove the heat from the power module 11, inductor 12, and film capacitor 13, using a coolant, such as water, in the water-cooling type, when the motor driving system operates.

Accordingly, in the present invention, in contrast to the related art, the temperature around where the film capacitor 13 operates is not the temperature of the engine room, but the temperature of the coolant that is relatively low, such that it is possible to additionally ensure tolerance in temperature to the limit temperature for the film capacitor 13.

As described above, according to the apparatus 100 for cooling heating parts of hybrid electric vehicles according to the present invention, it is possible to improve cooling efficiency for the entire motor driving system, because the film capacitor 13 is mounted on the heat dissipater 30, in addition to cooling the power module 11 and the inductor 12 by using the heat dissipater 30.

Therefore, because it is possible to maximize the effect of cooling the entire motor driving system by making the temperature of the surrounding of the film capacitor 13 at the level of the temperature of the coolant, not the temperature of the engine room, it is possible to improve the commercial value and performance of a vehicle by increasing the capacity of the inverter, including the film capacitor 13.

Further, it is possible to reduce the entire size and weight of the motor driving system without using a specific heat-dissipating apparatus for cooling the film capacitor 13, because the power module 11 and the inductor 12 are mounted on one side of the heat dissipater 30 and the film capacitor 13 is mounted on the other side.

The reduction of weight of the parts contributes to improving fuel efficiency of a vehicle and reducing the manufacturing cost.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of symbols>

| | | | |
|---|---|---|---|
| 11 | Power module | 12 | Inductor |
| 13 | Film capacitor | 15 | Case |
| 30 | Heat dissipater | 31 | Channel |
| 41 | Inverter housing | 51 | Heat-dissipating plate |
| 53 | Rib | 61 | Cover |
| HR1, HR2 | Heat transfer path | | |

What is claimed is:

1. A cooling apparatus for cooling the main heating parts of a motor driving system in a hybrid electric vehicle comprising:
an inverter,
wherein a heat dissipater equipped with a plurality of heating parts is included, such that the heating parts share the heat dissipater and a channel for a coolant to flow is formed in the heat dissipater, and the heat dissipater defines heat transfer paths for transferring heat generated from the plurality of heating parts to the coolant,
wherein the plurality of heating parts includes a power module, an inductor, and a film capacitor.

2. The apparatus of claim 1, wherein the heat transfer path for the power module and the inductor and the heat transfer path for the film capacitor are formed in the opposite directions in the heat dissipater.

3. The apparatus of claim 1, wherein the heat dissipater is equipped with the power module and the inductor on one side and the film capacitor on the other side.

4. The apparatus of claim 1, wherein the heat dissipater includes a heat-dissipating plate forming the channel and a cover combined with the heat-dissipating plate and covering the channel.

5. The apparatus of claim 4, wherein the power module and the inductor are disposed on a flat surface of the heat-dissipating plate and the film capacitor is disposed on a flat surface of the cover in the heat dissipater.

6. The apparatus of claim 4, wherein the channel of the heat-dissipating plate is formed in a zigzag shape and positioned between a plurality of ribs.

7. The apparatus of claim 1, wherein the heat dissipater is connected with an inverter housing covering the power module and the inductor.

8. The apparatus of claim 4, wherein the cover serves as a case for the film capacitor.
